(19) United States
(12) Patent Application Publication
(10) Pub. No.: US 2009/0187368 A1
(43) Pub. Date: Jul. 23, 2009

(54) Burn-In Tests To Produce Fabricated Integrated Circuits With Reduced Variations Due To Process Spread

(75) Inventor: Palkesh Jain, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/354,794

(22) Filed: Jan. 16, 2009

(30) Foreign Application Priority Data
Jan. 21, 2008 (IN) 173/CHE/2008

(51) Int. Cl. G01R 31/26

(52) U.S. Cl. 702/119; 324/765

(57) ABSTRACT

An aspect of the present invention enables burn-in tests to reduce variations due to process spread in fabricated integrated circuits (IC). Fabricated ICs are classified into multiple categories based on performance characteristics (e.g., operational speed) indicative of the extent of process spread in the ICs. The ICs are subjected to burn-in tests, with the severity of stress parameters applied during a burn-in test being proportional to the performance characteristics. As a result, process spread exhibited by the ICs (post burn-in) is reduced.

### RELATED APPLICATION(S)

The present application claims the benefit of co-pending India provisional application serial number: 173/CHE/2008, entitled: “Process Corner Specific Burn-In Optimization for Controlling Process Spread”, filed on 21, Jan. 2008, naming Texas Instruments Inc. (the intended assignee) as the Applicant, and naming the same inventors as in the present application as inventors, attorney docket number: TXN-935, and is incorporated in its entirety herewith.

### BACKGROUND

1. Field of the Invention

The present invention relates generally to integrated circuit (IC) design and fabrication, and more specifically to burn-in tests to produce fabricated integrated circuits with reduced variations due to process spread.

2. Related Art

Fabricated integrated Circuits (ICs) often display variations in their performance characteristics, despite being all designed according to a same design specification. Such variations in performance characteristics may include operational speed, leakage power, etc. For example, a batch of ICs may be designed for a targeted (desired) operation of 100 MHz (clock speed). However, after fabrication, some of the ICs may display operational speeds greater and/or less than the desired 100 MHz speed, in addition to some at the desired speed. The term ‘IC’ refers to both a fabricated die (containing the desired circuit, but before encapsulation in a package), as well as a packaged die (containing external leads, etc).

Fabricated ICs are often subjected to burn-in tests. As is well known, a burn-in test refers to subjecting each IC to operational and environmental conditions exceeding normal (targeted) conditions. For example, during a burn-in test, fabricated ICs may be operated using a power supply voltage exceeding a rated (desired) voltage at which the ICs are designed to operate, and in ambient conditions (temperature, pressure, etc.,) higher (or lower) than a normal range. Depending on the specific requirements, the ICs may be tested under various other “stress” conditions in addition to those noted above. As is further well known, burn-in tests are generally designed to cause potential fault conditions in the ICs to manifest during the test rather than during normal operation, thereby avoiding shipment of ICs susceptible to failure during normal operation.

Process spread (also termed statistical process variation) generally refers to statistical variations (spread) present in ICs, due to variations in fabrication steps. For example, the quantity of dopant(s) used to create ‘n’ and ‘p’-type regions of an IC may not be uniform for all dies on a wafer, or for different wafers. Similarly, variations in the masking process (e.g., imperfectly aligned masks) may be slightly different for different dies and wafers, and may result in channel widths of transistors to be different on different dies. In general, process spread may result from, among others, variations in raw material properties, processing material quantities, variations in the fabrication steps, etc. One measure of process spread is the operational speed of an IC (e.g., as may be measured by the output frequency of an oscillator in the IC).

As may be appreciated, at least very wide variations in operational characteristics of ICs may not be desirable. As an example, ICs with operational speeds above or below a predetermined range may be deemed unsuitable for use, and may be discarded, leading thereby to a reduction in production yield, and thereby enhanced average cost. Several features of the present invention enable integrated circuits (after being subjected to burn-in tests) with reduced variations to be provided.

### SUMMARY

An aspect of the present invention enables burn-in tests to reduce variations due to process spread in fabricated integrated circuits (IC). In an embodiment, the fabricated ICs are classified into multiple categories based on performance characteristics (e.g., operational speed) indicative of the extent of process spread in the ICs. The ICs are subjected to burn-in tests, with the severity of stress parameters applied during a burn-in test being proportional to the performance characteristics. As a result, process spread exhibited by the ICs (post burn-in) is reduced.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### BRIEF DESCRIPTION OF THE DRAWINGS

The present invention will be described with reference to the following accompanying drawings, which are described briefly below.

FIG. 1 is a block diagram illustrating a prior design flow cycle for an IC.

FIG. 2 is a graph illustrating example variations due to process spread distribution.

FIG. 3 is a flowchart illustrating the manner in which burn-in test is used to reduce variations in post burn-in ICs, in an embodiment of the present invention.

FIG. 4A is a graph illustrating an example process spread of ICs after a burn-in test in an embodiment of the present invention.

FIG. 4B is a graph illustrating the changes in threshold voltage of ICs with operational time/duration.

FIG. 5 is a block diagram illustrating a design flow for ICs in an embodiment of the present invention.

FIG. 6 is a block diagram illustrating the details of a test system in which several aspects of the present invention are operative by execution of appropriate software instructions.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

The features of the present invention are described below with several examples for illustration. However, various features of the present invention will be clearer in comparison with a prior approach. Accordingly, the description of a prior approach is provided first.

1. Prior IC Design Cycle

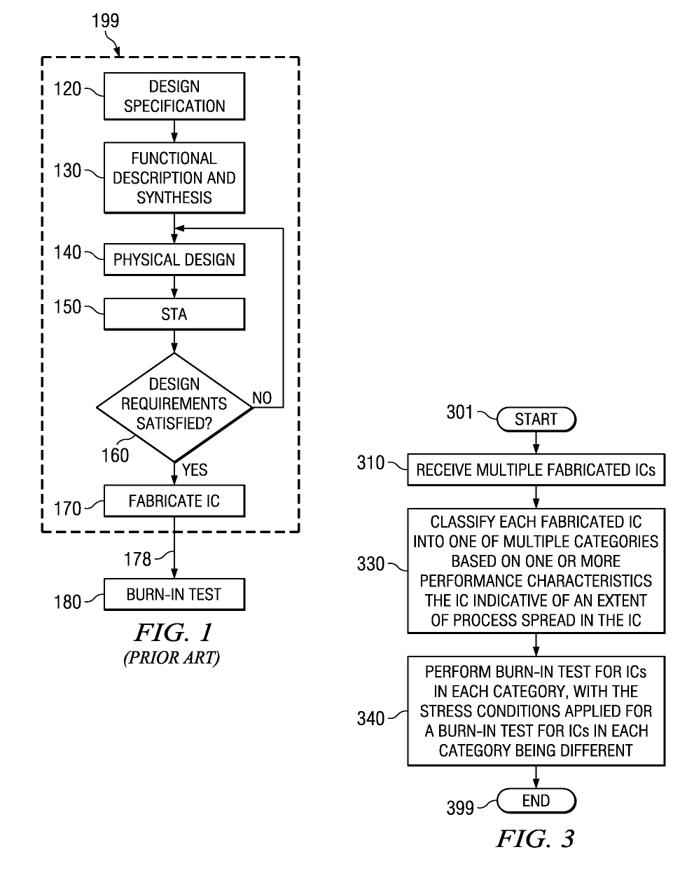

FIG. 1 is a diagram illustrating a prior design flow cycle for an IC. The design flow is shown merely for the purpose of illustration, and may include other/alternative phases, and possibly other sequences of the phases as well. The design may start with design specifications (120) of the IC (circuit), in which the specifications of an IC may be generated. A functional description and synthesis (130) phase may be performed next to create the circuit, a netlist (specifying interconnections between the various components/blocks in the circuit), as well as libraries of the components contained in the circuit.

Physical design (140) may be performed next, and generally involves placement of components in the circuit (represented by the corresponding netlist and libraries), and routing the interconnection(s) (signals, etc.) between the components. Physical design (140) may be performed ensuring that timing requirements (e.g., setup and hold times) of various signals in the IC are satisfied. Physical design (140) may generate as outputs, the physical layout of the components in the circuit, post-placement timing of various signals in the circuit, information regarding parasitic elements in the physical layout, etc. Physical design (140) maybe performed in a manner consistent with several design requirements to be met (e.g., area of the placed and routed circuit, timing requirements, power consumption, etc).

Static timing analysis (STA) 150 may be performed as a next phase, in which the arrival times of the signals at various paths/nodes in the circuit (IC) are estimated, typically based on delay models (gate delays, connection-path or wire delays, etc., based on the output of the physical design phase 140). The timings at the various nodes in the design may be checked against desired timing requirements (i.e., a comparison of arrival times against required times is made, whether set-up and hold times of clocked components/registers are satisfied, etc.).

If the design requirements (timing, area, etc., noted above) are satisfied (decision block 160), the output of the physical design process is sent for fabricating (170) the IC. If the design requirements are not met, then physical design (140) may be performed again. In some instances, functional description and synthesis (130) may be repeated with corresponding modifications, and the following phases may be repeated till the design requirements are met. Thus, the design flow procedure noted above may be iterative.

After fabrication (170), the ICs are tested (burn-in test 180) to isolate/identify potentially faulty defective chips. As noted above, burn-in test (180) may be performed to subject the fabricated ICs to “stress” conditions (e.g., temperatures and power supply voltages exceeding rated values). During the test, various test patterns may be applied to the circuits to cause the circuits to operate at corresponding “levels” of operation. For example, a slowly varying sequence of bits (toggling between logic 1 and logic 0) may be provided to stress the ICs to a lower ‘level’, while a faster variation in the sequence (e.g., bit toggles for every clock interval) may be applied to stress the ICs to a greater ‘level’. Several other parameters (in addition to, or in conjunction with, temperature, and power supply voltage and test patterns) may be used for subjecting the ICs to stress. These parameters (the temperature, supply voltage, bit patterns, duration of test, etc.) are termed as stress parameters since these parameters affect the electrical characteristics of the ICs during testing.

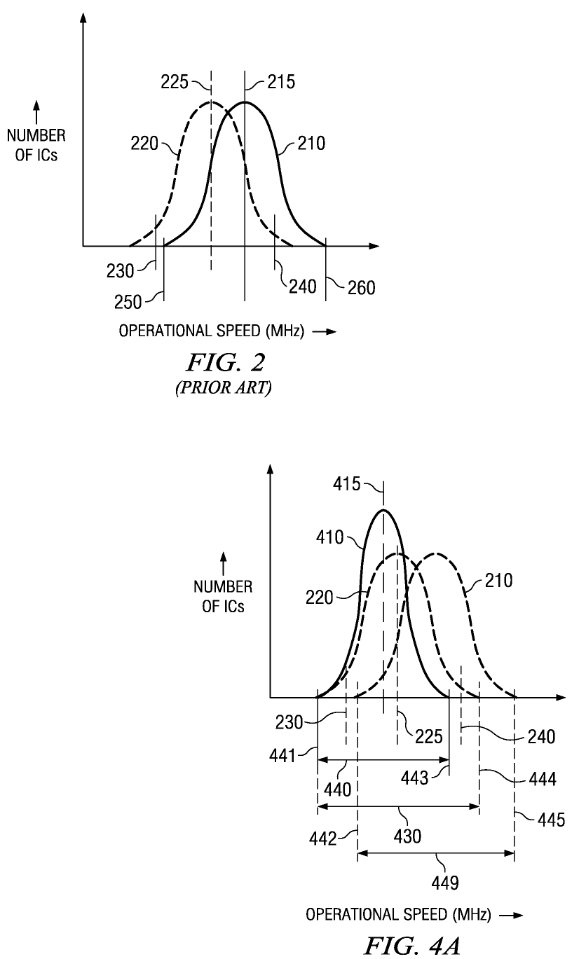

As noted above, due to process spread, fabricated ICs (containing the same circuit) may exhibit variations in their characteristics. Burn-in test (180) alters the process spread. Assuming the same (uniform) stress conditions are applied to all ICs (as in the case of burn-in test 180), the variations due to process spread are shifted by a corresponding constant amount, as illustrated with respect to FIG. 2.

FIG. 2 is a graph illustrating variations in operational characteristics of ICs with respect to an example process spread. For ease of description, the variations in operational characteristics are also referred to below as process spread, although it may be appreciated that the variations are an effect of process spread.

Distribution 210 shows the variations prior to burn-in test, while (dotted) distribution 220 shows the variations after a burn-in test. Distribution 210 is shown as a Gaussian spread, with the mean denoted by marker 215. However, it may be appreciated that other types of distributions are also possible. ICs with speed denoted by marker 215 have the desired (target) operating speed (as well as other desired operational characteristics, such as acceptable leakage currents, etc). ICs represented by portions of distribution 210 to the left of mean 215 have progressively slower speeds (but lower leakage currents), while those to the right of mean 215 have progressively greater speeds (but higher leakage currents, and therefore higher static power consumption). Markers 250 and 260 denote the minimum and maximum values (speed) of process spread distribution 210. It is noted that the minimum (250) and maximum (260) values may have a same magnitude of deviation from mean 215.

Burn-in test 180 causes distribution 210 to be shifted to the left, and the shifted distribution 220 represents the process spread (for the same number of ICs as distribution 210) after the burn-in test. The characteristics (shape, etc) of the distribution represented by distribution 220 are the same as that of distribution 210, except for a shift (represented by the difference in the mean 215 of distribution 210 and 225 of distribution 220. Thus, the extent of variation after burn-in (as may be represented by the variance of Gaussian distribution 220) generally remains the same as that of Gaussian distribution 210.

It is noted that some of the causes of IC failure (or faulty operation) include Negative Bias Temperature Instability (NBTI) and hot-carrier injection, or other operational-lifetime degradation phenomena, including electro-migration. As is well-known in the relevant arts, NBTI is a phenomenon that affects p-channel MOS devices stressed with negative gate voltages, and which may cause an increase in the threshold voltage (Vt) of the corresponding device, thereby reducing the operational speed of circuit portions employing such devices. Hot carrier injection may cause leakage currents in transistors to increase.

Burn-in test 180 further subjects components (such as transistors) in ICs to NBTI and hot-carrier injection effects, thereby further degrading their performance characteristics. The shifting of distribution 210 to distribution 220 represents a uniform degradation (aging) in the ICs caused by burn-in test 180, due to effects that include NBTI and hot carrier injection.

Although, not described with respect to FIG. 1, a measurement phase may be performed subsequent to burn-in test 180, to measure the performance characteristics of each fabricated IC. For example, the speed of operation of each IC may be determined by measuring the frequency of an output signal of a ring oscillator contained in the IC. The fabricated ICs may then be speed-graded (grouped in corresponding speed ranges) based on the measurements. It may be determined that all ICs with speeds less than that indicated by marker 230, or greater than that indicated by marker 240 may be susceptible to failure during normal use, and therefore be discarded. The specific positions of markers 230 and 240 with respect to distribution 220 (and therefore the number of ICs to the left of marker 230, and to right of marker 240) are shown merely by way of example.

The criteria for discarding may be different from those shown in FIG. 2. For example, assuming speed is the primary concern, more number of slower ICs (lying in portions to the left of mean 225) may be discarded. If leakage power is the primary concern, more number of faster ICs (lying in portions to the right of mean 225) may be discarded. Various other considerations may also be used to determine the number and specific ones of ICs discarded, or dealt with separately (e.g., use for less demanding environments or provide work-around). Even assuming that all ICs represented by distribution 220 are deemed suitable for normal use, the extent of variations in their operational characteristics may necessitate additional design complexity when incorporating such ICs in a system/device.

One prior approach to addressing process spread in ICs is adaptive voltage scaling (AVS), in which additional circuitry may be added to each of the ICs to measure speed reduction/change, and to compensate by proportionately changing the power supply voltage provided to components in the IC, thereby nullifying the speed reduction. Another prior approach is adaptive body bias, in which the potential to which the substrate of a transistor is connected is changed adaptively, to alter the threshold voltage (Vt). Such prior approaches may not be desirable due to the associated increase in cost, size of the ICs, as well as the increased design complexity.

In yet another prior approach, additional timing margins for various signals in an IC (and therefore wider overall timing requirements) may be set, to compensate for degradation due to process spread, as well as burn-in test related aging. However, such an approach may render several design phases (e.g., iterative phases 140, 150 and 160 of FIG. 1) to be complex and long, and/or difficult to perform.

Several features of the present invention reduce process spread in fabricated ICs, as described in detail below.

2. Burn-in Test to Reduce Process Spread

FIG. 3 is a flowchart illustrating the manner in which burn-in test is used to reduce process spread. The flowchart is provided merely by way of illustration, and other techniques, steps, and/or sequence of steps can also be implemented to create the optimized model without departing from the scope and spirit of several aspects of the present invention, as will be apparent to one skilled in the relevant arts on reading the disclosure herein. The flowchart starts in step 301, in which control passes immediately to step 310.

In step 310, multiple ICs are received. All the ICs contain the same circuit design (the output of 140), and are fabricated according to a same fabrication procedure (same sequence of steps, technique, etc.). Control then passes to step 330.

In step 330, each fabricated IC is classified into one of multiple categories based on one or more performance characteristics of the IC. A performance characteristic is selected to be indicative of (be a measure of) an extent of process spread in the IC. The extent of process spread is determined considering both the magnitude as well as the sign (or direction) of the variation from a zero level used to compute/represent the spread. It should be appreciated that even ICs fabricated on a same wafer may have wide variations and thus the classification may be performed on an individual IC basis. Control then passes to step 340.

In step 340, burn-in test is performed for ICs in each category, with the stress conditions applied for ICs in one category being different from stress conditions applied for ICs in the other categories. This would mean that the tests are performed with different values (implying different stress levels) for the same stress parameter. For example, different temperatures may be used for different burn-in tests, subjecting the ICs of different bins to different stress levels (higher level implies more stress, therefore greater degradation in the electrical characteristics of the ICs). Control ends in step 390.

In an embodiment of the present invention, the ICs are sorted (binned) into corresponding ones of multiple speed (or speed-range) bins based on their measured operational speeds. The operational speeds may be measured prior to a burn-in test, for example, by measuring the frequency of a ring-oscillator in the ICs. Performance characteristics other than operational speed, like IC leakage currents, may also be used instead.

In the embodiment, each IC in a bin (speed range) is subjected to identical burn-in stress parameters (e.g., same power supply voltage, temperature, duration of test, same bits or bit-patterns applied as test patterns to ICs during burn-in test, same power down-conditions of portions of the ICs, etc.). However, ICs in a different bin are subjected to a different set of burn-in stress parameters. ICs in bins corresponding to lower speeds are subjected to proportionately lower burn-in stress (less severe stress parameters), while ICs in bins corresponding to higher speeds are subjected to proportionately higher burn-in stress (more severe stress parameters).

Thus, the extent of stress (severity of stress parameters) applied to an IC during burn-in testing is proportional to its performance characteristics (measured operational speed in the embodiment noted above). It may therefore be appreciated that a slower speed IC (closer to the lower or slower end of the spread) will age (be performance degraded) less than a higher speed IC (closer to the upper or faster end of the spread). Thus, by subjecting ICs to burn-in stress in a manner proportional to the performance characteristic(s) indicative of process spread due to manufacture, the final (post burn-in) process spread may be reduced.

In an embodiment of the present invention, ICs with the slowest measured speed (corresponding to a weak or slow process corner, well known in the relevant arts) are subjected to burn-in test with a same level of stress as would be applied in a conventional burn-in stress (prior burn-in test, corresponding to FIG. 2). ICs with higher speed are subjected to burn-in test with progressively greater stresses, with ICs at the strongest (fastest) process corner being subjected to greatest stress.

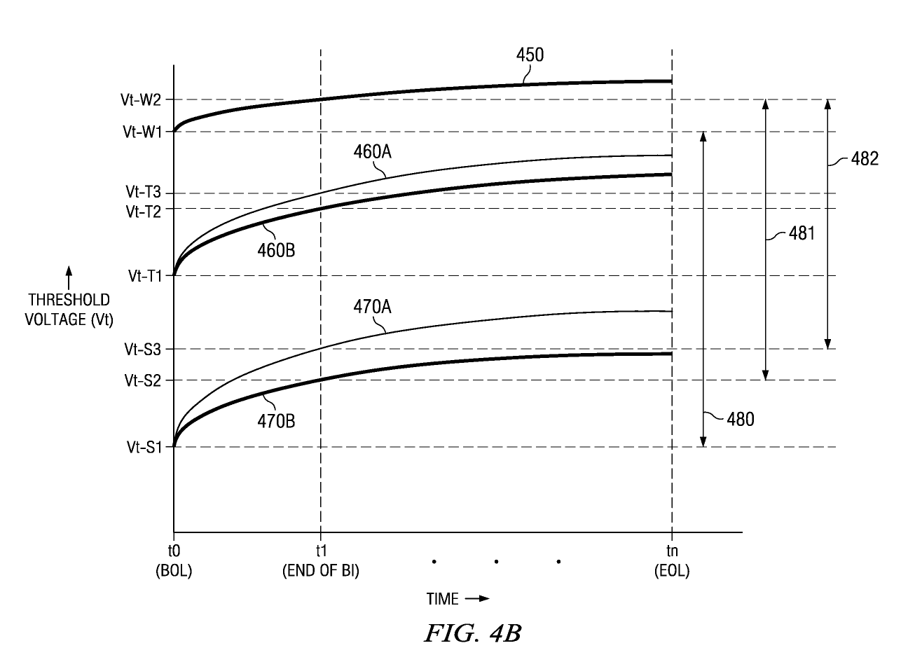

FIG. 4A is a graph illustrating an example process spread (Gaussian distribution 410) of ICs after burn-in test in an embodiment. Distribution 410 is a Gaussian distribution, representing the process spread of ICs after a burn-spread according to the present invention. Distribution 410 is shown as a continuous distribution for ease of illustration. However, it may be appreciated based on the description above, that the distribution may be discrete for a finite number of ICs, and based on the manner in which a burn-in test is performed. Distributions 210 and 220 of FIG. 2 may also be discrete distributions, although shown as being continuous.

It is assumed for the purpose of comparison that number of ICs (area under distribution 410) corresponding to FIG. 4A equals the number of ICs (area under distributions 220 and 210) corresponding to FIG. 2. Distributions 220 and 210 are repeated in FIG. 4A to enable easy visual comparison.

With respect to distributions 410 and 210, it may be observed that for the slowest ICs, the speed reduction (difference between speeds denoted by markers 442 and 441) is substantially the same as that in the case of prior distribution 220, since the slowest ICs are subjected to the same stress as in the prior case. However, for faster ICs, since the stresses applied are greater, the speed reduction is also proportionately greater when compared with prior distribution 220, as may be observed from FIG. 4A.

For the fastest ICs, the speed reduction is maximum (difference between speeds denoted by markers 445 and 443 in the present invention, as against markers 445 and 444 for the prior technique). It may therefore be appreciated that post burn-in (according to the present invention) process spread (process spread 440) is lesser than pre burn-in process spread 449. In the prior burn-technique (FIG. 2), there is no reduction in process spread resulting due to the burn-in test (process spread 449 and 430 are equal).

FIG. 4B is a graph illustrating the changes in threshold voltage (and hence the speed) of ICs as a function of operational duration/time. The changes in threshold voltage may occur, for example in PMOS devices due to NBTI effects, noted above. Curve 450 shows the variation (increase) in threshold voltage (Vt) for weak or slow ICs according to both the prior burn-in technique and burn-in according to the present invention. Curve 460B shows the variation (increase) in threshold voltage (Vt) of typical ICs (typical or nominal speed) for ICs according to the prior burn-in technique, while curve 460A shows the variation (increase) in threshold voltage (Vt) for typical ICs according to the burn-in technique of the present invention. Curve 470B shows the variation (increase) in threshold voltage (Vt) for strong or fast ICs according to the prior burn-in technique, while curve 470A shows the variation (increase) in threshold voltage (Vt) for typical ICs according to the burn-in technique of the present invention.

Time t0 represents the beginning of life (BOL) of the ICs, i.e., ICs as at end of fabrication. Time period t0 to t1 represents the duration of burn-in (assumed equal for all ICs in both the prior technique and present invention, for simplicity). Time tn represents the end of operational life (EOL) of the ICs. The extent of Vt variation prior to burn-in test is represented by the width of arrow 480. The extent of Vt variation at the end of burn-in test according to the prior technique is represented by the width of arrow 481. The extent of Vt variation at the end of burn-in test according to the present invention is represented by the width of arrow 482.

Similar to the overall reduction in process spread represented by width of arrow 440 (FIG. 4A), it may be observed that Vt variation represented by arrow 482 is less than that represented by arrow 481.

It may be appreciated that ICs obtained with reduced process spread by a burn-in test according to the present invention may substantially reduce any additional design complexity when incorporating such ICs in a system/device. Further, the number of ICs that may need to be discarded as being susceptible to failure during normal use (also termed field use) may be minimized. For example, in contrast to the prior technique, in which ICs to the right of marker 240 of distribution 220 may be deemed unsuitable for filed use, none (or fewer numbers) of the ICs of distribution 410 may need to be discarded. Thus, the reduced process spread improves yield, and reduces cost as well.

Further, any additional timing requirements (margins) that may need to be considered to compensate for process spread and/or burn-in test related aging, may be relaxed (minimized). As a result, several design phases (e.g., iterative phases 140, 150 and 160 of FIG. 1) may be performed with greater ease and speed (quicker design closure). ICs produced with lesser process spread may not need to include circuits or other techniques (e.g., adaptive voltage scaling, adaptive body bias, etc.) for handling process variations, although such techniques may be used additionally to handle the remaining variations in the ICs.

The manner in which the design flow of an IC is performed in an embodiment of the present invention is briefly described next.

3. Improved Design Flow

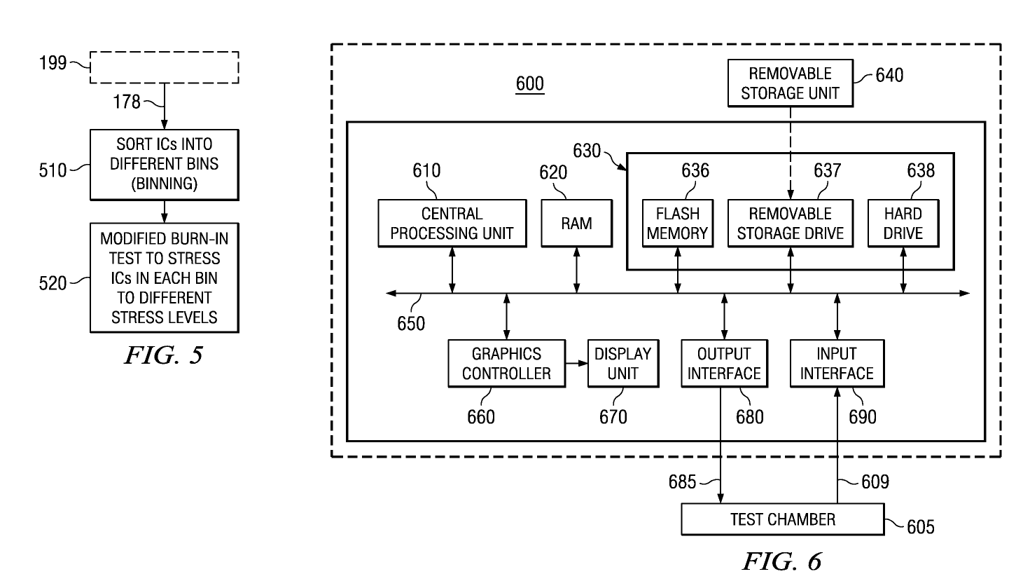

FIG. 5 is a diagram illustrating a design flow for ICs in an embodiment of the present invention. Various phases of the flow represented by box 199 are the same as that in box 199 of FIG. 1, and not repeated here in the interest of conciseness. It is noted however that the relevant operations in 199 may be performed using smaller timing margins.

Fabricated ICs (output represented by arrow 178) are sorted into different speed-range bins (binning 510). The sorting may be done based on measurement of the operating speeds of the ICs, in a manner as noted above, with the speeds determined by measuring the frequency of embedded test circuits (for e.g. ring oscillators) in the ICs. The number of bins to be used may conveniently be selected by a designer or test engineer based on practicality and cost (time, resources required, etc.). In general, more number of bins cause finer (more granular) stress application.

In burn-in test phase (520) the ICs in the bins are subjected to burn-in test, with the stress applied during the test being proportional (i.e., having positive correlation) to the speed corresponding to the bin, as noted above, to provide ICs with reduced process spread.

Several features of the present invention may be provided in a test system to perform burn-in tests in the manner described in detail above. Such a test system may be implemented using software, hardware, or a combination of hardware and software. In general, when throughput performance is of primary consideration, the implementation is performed more in hardware (e.g., in the form of an application specific integrated circuit). When cost is of primary consideration, the implementation is performed more in software (e.g., using a processor executing instructions provided in software/firmware).

Cost and performance can be balanced by employing a mix of hardware, software and/or firmware. An example embodiment implemented substantially in software is described next.

4. Burn-In Test System

FIG. 6 is a block diagram of an example test system 600 used to perform burn-in tests in an embodiment of the present invention. A test chamber 605 is also shown. Test system 600 may contain one or more processors such as a central processing unit (CPU) 610, random access memory (RAM) 620, secondary memory 630, graphics controller 660, display unit 670, output interface 680 and input interface 690. All the components (except display unit 670) may communicate with each other over communication path 650, which may contain several buses as is well known in the relevant arts.

Test chamber 605 is a device in which ICs are placed during a burn-in test. ICs may be placed on corresponding connection points of one or more test jigs inside test chamber 605. Electrical wires (e.g., paths 685 and 609) may be provided to carry information between test system 600 and test chamber 605.

CPU 610 may execute instructions stored in RAM 620 to provide several features of the present invention. CPU 610 may contain multiple processing units, with each processing unit potentially being designed for a specific task. Alternatively, CPU 610 may contain only a single general-purpose processing unit. RAM 620 may receive instructions from secondary memory 630 using communication path 650.

CPU 610 executes instructions in RAM 620 to provide to test chamber 605 (on path 685) temperature values, power supply values, test patterns, duration of burn-in test, etc., corresponding to each ‘speed bin’ for a burn-in test. CPU 610 may receive outputs of ICs (e.g., bit-patterns, oscillator outputs, etc) on path 609. The interaction and operation of test system 600 and test chamber 605 may be semi-automated or fully automated, to perform burn-in test for all ICs (all speed bins).

For example, a batch of ICs may be placed in test chamber 605, and CPU 610 (by execution of appropriate software instructions) may determine the specific bin (of FIGS. 3 and 4A) to which the ICs belong (for example, by measuring the frequency of an oscillator) and set the various parameters for burn-in tests as described above.

Input interface 690 may correspond to a keyboard and a pointing device (e.g., touch-pad, mouse) and may be used to provide user inputs. In addition, input interface 690 contains input ports to receive external inputs from test chamber 605, as shown. Output interface 680 provides outputs of test system 600 to test chamber. The outputs control various parameters during burn-in tests, as described above.

Secondary memory 630 may contain hard drive 638, flash memory 636, and removable storage drive 637. Secondary memory 630 may store the data (e.g., temperature values, power supply values, test patterns, duration of burn-in test, etc, corresponding to each ‘speed bin’ for a burn-in test) and software instructions, which enable test system 600 to provide several features in accordance with the present invention. Some or all of the data and instructions may be provided on removable storage unit 640, and the data and instructions may be read and provided by removable storage drive 637 to CPU 610. Floppy drive, magnetic tape drive, CD-ROM drive, DVD Drive, Flash memory, removable memory chip (PCMCIA Card, EPROM) are examples of such removable storage drive 637.

Removable storage unit 640 may be implemented using media and storage formats compatible with removable storage drive 637 such that removable storage drive 637 can read the data and instructions. Thus, removable storage unit 640 includes a computer readable (storage) medium having stored therein computer software and/or data. However, the computer (or machine, in general) readable medium can be in other forms (e.g., non-removable, or removable, etc.).

In this document, the term “computer program product” is used to generally refer to removable storage unit 640 or hard disk installed in hard drive 638. These computer program products are means for providing software to test system 600. CPU 610 may retrieve the software instructions, and execute the instructions to provide various features of the present invention described above.

Reference throughout this specification to “one embodiment”, “an embodiment”, or similar language means that a particular feature, structure, or characteristic described in connection with the embodiment is included in at least one embodiment of the present invention. Thus, appearances of the phrases “in one embodiment”, “in an embodiment” and similar language throughout this specification may, but do not necessarily, all refer to the same embodiment.

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. A method of performing a burn-in test for integrated circuits, the method comprising:
receiving an integrated circuit (IC);
classifying the IC into a category of a plurality of categories based on one or more performance characteristics indicative of an extent of process spread in the IC; and
subjecting the IC to the burn-in test depending on a characteristic of the category of the plurality of categories,
wherein a level of a stress parameter applied during the burn-in test for the IC is according to the characteristic of the category.

2. The method of claim 1, wherein a first category corresponds to a slower process corner, and a second category corresponds to a faster process corner, the first category and the second category being contained in the plurality of categories,
wherein a severity of the stress parameter applied during burn-in test for ICs in the first category is lesser than a severity of the parameter applied during burn-in test for ICs in the second category.

3. The method of claim 2, wherein the one or more performance characteristics comprises an operational speed of the IC,
wherein the classifying comprises measuring the operational speed of the IC and including the IC in a corresponding one of the plurality of categories based on the operational speed,
wherein the severity of the parameter applied during the burn-in test is greater for a greater value of the operational speed.

4. The method of claim 3, wherein the stress parameter applied during the burn-in test comprises one of a temperature, a power supply voltage, a duration of the burn-in test, and a bit pattern.

5. A method of performing a burn-in test for integrated circuits (IC), said method comprising:
receiving a plurality of fabricated ICs;
classifying said plurality of fabricated ICs into a plurality of categories based on one or more performance characteristics indicative of an extent of process spread in the IC; and
subjecting ICs in each of said plurality of categories to said burn-in test,
wherein a level of a stress parameter applied during said burn-in test for a first IC in a first category is different from a level of said stress parameter applied during said burn-in test for a second IC in a second category.

6. The method of claim 5, wherein said first category corresponds to a slower process corner, and said second category corresponds to a faster process corner,
wherein a severity of said stress parameter applied during burn-in test for ICs in said first category is lesser than a severity of said parameter applied during burn-in test for ICs in said second category.

7. The method of claim 5, wherein said one or more performance characteristics comprises an operational speed of a corresponding IC,
wherein said classifying comprises measuring the operational speed of each of said plurality of ICs and including the ICs with a corresponding range of operational speeds in a corresponding one of said plurality of categories,
wherein the severity of said parameter applied during said burn-in test is greater for a greater value of said operational speed.

8. The method of claim 5, wherein said stress parameter applied during said burn-in test comprises one of a temperature, a power supply voltage, a duration of said burn-in test, and a bit pattern.

9. A computer readable medium storing one or more sequences of instructions causing a test system to perform a burn-in test for integrated circuits (IC), wherein execution of said one or more sequences of instructions by one or more processors contained in said system causes said system to perform the actions of:
receiving a plurality of fabricated ICs;
classifying said plurality of fabricated ICs into a plurality of categories based on one or more performance characteristics indicative of an extent of process spread in the IC; and
subjecting ICs in each of said plurality of categories to said burn-in test,
wherein a level of a stress parameter applied during said burn-in test for a first IC in a first category is different from a level of said stress parameter applied during said burn-in test for a second IC in a second category.

10. The computer readable medium of claim 9, wherein said first category corresponds to a slower process corner, and said second category corresponds to a faster process corner,
wherein a severity of said stress parameter applied during burn-in test for ICs in said first category is lesser than a severity of said parameter applied during burn-in test for ICs in said second category.

11. The computer readable medium of claim 10, wherein said one or more performance characteristics comprises an operational speed of a corresponding IC,
wherein said classifying comprises measuring the operational speed of each of said plurality of ICs and including the ICs with a corresponding range of operational speeds in a corresponding one of said plurality of categories,
wherein the severity of said parameter applied during said burn-in test is greater for a greater value of said operational speed.

12. The computer readable medium of claim 11, wherein said stress parameter applied during said burn-in test comprises one of a temperature, a power supply voltage, a duration of said burn-in test, and a bit pattern.
